(19) United States
(12) Patent Application Publication
(10) Pub. No.: US 2009/0040078 A1
(43) Pub. Date: Feb. 12, 2009

(54) METHOD FOR DIFFERENTIATING KEYS AND RELATED COMPUTER APPARATUS

(76) Inventors: Wan-Chi Lan, Taipei Hsien (TW); Yu-Cheng Hua, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/847,350

(22) Filed: Aug. 30, 2007

(30) Foreign Application Priority Data
Aug. 8, 2007 (TW) 096129299

(51) Int. Cl. H03K 17/94; H03M 11/00

(52) U.S. Cl. 341/26

(57) ABSTRACT

A method for differentiating keys includes setting a first layer application program and a second layer application program, detecting whether the second layer application program is executed to generate a detection result, and selectively utilizing the first layer application program or the second layer application program to determine an event corresponding to a scan code when receiving the scan code corresponds to a key.

### BACKGROUND OF THE INVENTION

1. Field of the Invention

The present invention relates to a method and related computer apparatus for differentiating keys, and more particularly, to a method and related computer apparatus through detecting whether a second layer application program is executed to selectively utilize a first layer application program or the second layer application layer to determine an event corresponding to a scan code.

2. Description of the Prior Art

In Microsoft's Windows graphical user interface, although the use of a mouse can handle lots of operations, the cooperation with keyboard hotkeys can make work more efficient, providing a user with a quick way to start and operate desired application programs.

To use Microsoft-defined scan codes as keyboard scan codes, it must first pass through Microsoft's certification before Microsoft's certification logo can be affixed. Furthermore, if other scan codes not defined by Microsoft are to be used as keyboard scan codes, and if any amendments have been made to the keyboard's programming, then the keyboard must be resubmitted for Microsoft's certification. This reiterative process is not only time-consuming and laborious, but also increases costs whenever the Microsoft's certification is resubmitted. For manufacturers, it is really a thorny issue.

### SUMMARY OF THE INVENTION

It is one of the objectives of the claimed invention to provide a method for differentiating keys and related computer apparatus to solve the abovementioned problems.

The present invention discloses a method for differentiating keys. The method includes setting a first layer application program and a second layer application program, detecting whether the second layer application program is executed to generate a detection result when receiving a scan code corresponds to a key, and selectively utilizing the first layer application program or the second layer application program to determine an event corresponding to the scan code.

In one embodiment, when the detection result indicates that the second layer application program is executed, the first layer application program is used to transmit the scan code to the second layer application program, and the second layer application program is used to execute the event corresponding to the scan code defined in the second layer application program. In another embodiment, when the detection result indicates that the second layer application program is not executed, the first layer application program is used to execute the event corresponding to the scan code defined in the first layer application program.

The present invention discloses a computer apparatus. The computer apparatus includes a keyboard and a computer host. The keyboard has at least one key. The computer host is coupled to the keyboard. The computer host includes a first layer application program and a second layer application program. When receiving a scan code corresponding to the key, the computer host detects whether the second layer application program is executed to generate a detection result, and selectively utilizes the first layer application program or the second layer application program to determine an event corresponding to the scan code according to the detection result.

In one embodiment, the computer host includes a keyboard scan code generating module, a first processing module, and a second processing module. The keyboard scan code generating module is coupled to the keyboard for generating the scan code corresponding to the key when the key is pressed. The first processing module is coupled to the keyboard scan code generating module for detecting whether the second layer application program is executed when receiving the scan code corresponding to the key received from the keyboard scan code generating module. The second processing module is coupled to the first processing module. When the first processing module detects that the second layer application program is executed, the first processing module transmits the scan code to the second processing module and the second processing module executes the event corresponding to the scan code defined in the second layer application program.

In one embodiment, the first processing module is implemented by executing the first layer application program through a central processing unit, and the second processing module is implemented by executing the second layer application program through the central processing unit.

The present invention discloses a computer apparatus. The computer apparatus includes a keyboard, a keyboard controller, a first processing module, and a second processing module. The keyboard has at least one key. The keyboard controller is used for generating a scan code corresponding to the key when the key is pressed. The first processing module is used for detecting whether the second layer application program is executed when receiving the scan code corresponding to the key. The first processing module executes an event corresponding to the scan code defined in the first layer application program when the second layer application program is not executed. When the first processing module detects that the second layer application program is executed, the first processing module transmits the scan code to the second processing module and the second processing module executes an event corresponding to the scan code defined in the second layer application program.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart showing a method for differentiating keys according to an exemplary embodiment of the present invention.

FIG. 2 is a diagram of a computer apparatus for differentiating keys according to an embodiment of the present invention.

FIG. 3 is a diagram of a computer apparatus for differentiating keys according to another embodiment of the present invention.

FIG. 4 is a brief diagram of an example of the keyboard in FIG. 2.

FIG. 5 is a flowchart showing a method for differentiating keys according to another exemplary embodiment of the present invention.

### DETAILED DESCRIPTION

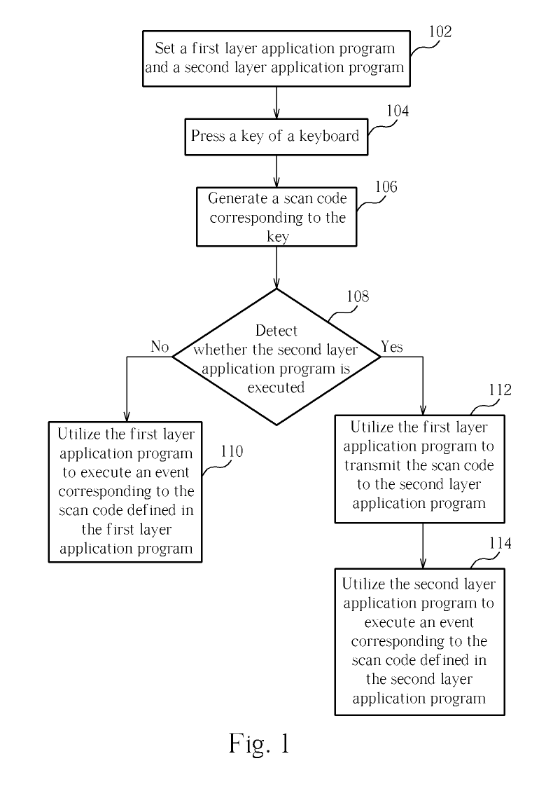

Please refer to FIG. 1. FIG. 1 is a flowchart illustrating a method for differentiating keys according to an exemplary embodiment of the present invention. Please note that the following steps are not limited to be performed according to the sequence shown in FIG. 1 as long as a roughly identical result can be obtained. The method includes the following steps:

Step 102: Set a first layer application program and a second layer application program.

Step 104: Press a key of a keyboard.

Step 106: Generate a scan code corresponding to the key.

Step 108: Detect whether the second layer application program is executed. If the second layer application program is executed, go to Step 112; otherwise, go to Step 110.

Step 110: Utilize the first layer application program to execute an event corresponding to the scan code defined in the first layer application program.

Step 112: Utilize the first layer application program to transmit the scan code to the second layer application program.

Step 114: Utilize the second layer application program to execute an event corresponding to the scan code defined in the second layer application program.

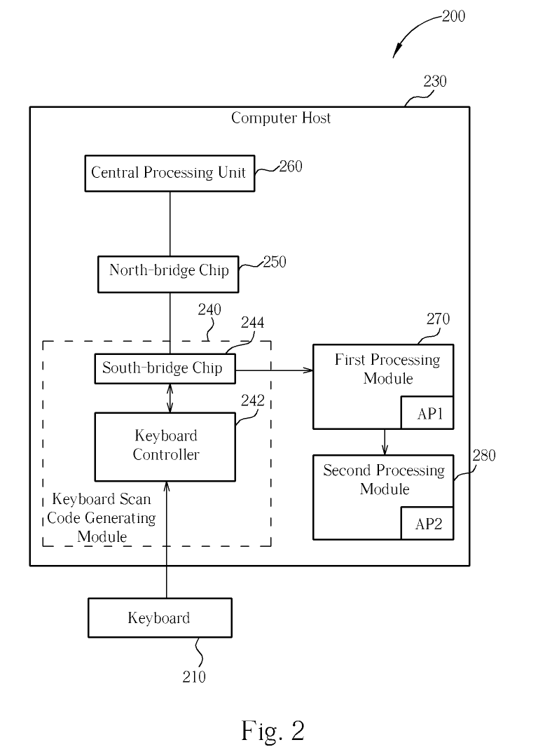

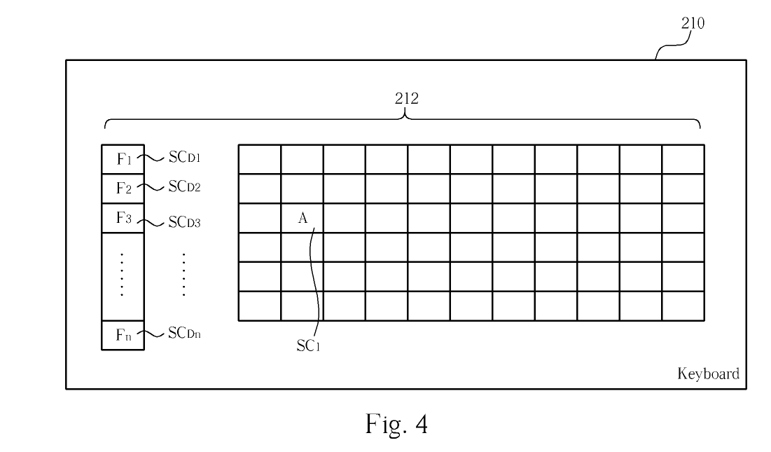

Please refer to FIG. 2. FIG. 2 is a diagram of a computer apparatus 200 for differentiating keys according to an embodiment of the present invention. The computer apparatus 200 includes a keyboard 210 and a computer host 230. The keyboard 210 is coupled to the computer host 230. The keyboard 210 has at least one key, whereof the keys include a plurality of hotkeys (please refer to FIG. 4 hereafter) corresponding to a plurality of designated scan codes (such as SC_{D1}-SC_{Dn}). The computer host 230 is coupled to the keyboard 210 and includes a first layer application program AP1 and a second layer application program AP2. When receiving a scan code corresponding to a key, the computer host 230 detects whether the second layer application program AP2 is executed to generate a detection result and selectively utilizes the first layer application program AP1 or the second layer application program AP2 to determine an event corresponding to the scan code according to the detection result. Please note that the “computer host” indicated in the present invention is an assembly of computer components coupled to the keyboard 210, but does not mean that the keyboard 210 is limited to be apart from the computer host: the keyboard 210 can be integrated or built into the computer host 230, and this also belongs to the scope of the present invention. The operations of the keyboard 210, the first layer application program AP1, and the second layer application program AP2 will be explained in detail in the following embodiments.

Please continue referring to FIG. 2. The computer host 230 includes, but is not limited to, a keyboard scan code generating module 240, a north-bridge chip 250, a central processing unit 260, a first processing module 270, and a second processing module 280. The keyboard scan code generating module 240 is coupled to the keyboard 210 for generating a scan code corresponding to a key (such as a hotkey, but the layered key differentiating mechanism of the present invention is not limited to a hotkey) when the key of the keyboard 210 is pressed. The keyboard scan code generating module 240 includes a keyboard controller (KBC) 242 and a south-bridge chip 244. When a user presses a key, the keyboard controller 242 issues an interrupt request (IRQ) to the south-bridge chip 244. The south-bridge chip 244 inquires which key is pressed through the operating system (OS) and then generates a corresponding scan code SC to the first processing module 270. The north-bridge chip 250 is used for coupling the south-bridge chip 244 and the central processing unit 260, but the operations of the north-bridge chip 250 are not the emphasis of the present invention and are therefore not detailed herein. The first processing module 270 is coupled to the keyboard scan code generating module 240 and includes a first layer application program AP1, where when the first processing module 270 receives the scan code SC corresponding to the key generated from the keyboard scan code generating module 240, the first processing module 270 will check whether a second layer application program AP2 is executed. The second processing module 280 is coupled to the first processing module 270 and includes the second layer application program AP2. When the first processing module 270 detects that the second layer application program AP2 is executed, the first processing module 270 transmits the scan code to the second processing module 280 and the second processing module 280 executes the event corresponding to the scan code defined in the second layer application program AP2. On the other hand, when the first processing module 270 detects that the second layer application program AP2 is not executed, the first processing module 270 executes the event corresponding to the scan code defined in the first layer application program AP1. The operations of the keyboard scan code generating module 240, the first processing module 270, and the second processing module 280 are further detailed in the following embodiments.

Please note that the abovementioned first processing module 270 can be implemented by executing the first layer application program AP1 (which can be stored in any storage media of the computer host 230 to be accessed by the central processing unit 260) through the central processing unit 260, and the second processing module 280 can be implemented by executing the second layer application program AP2, but are not limited to this, and can be implemented through other ways. For example, the first processing module 270 and the second processing module 280 can be implemented through hardware, software, or their combination.

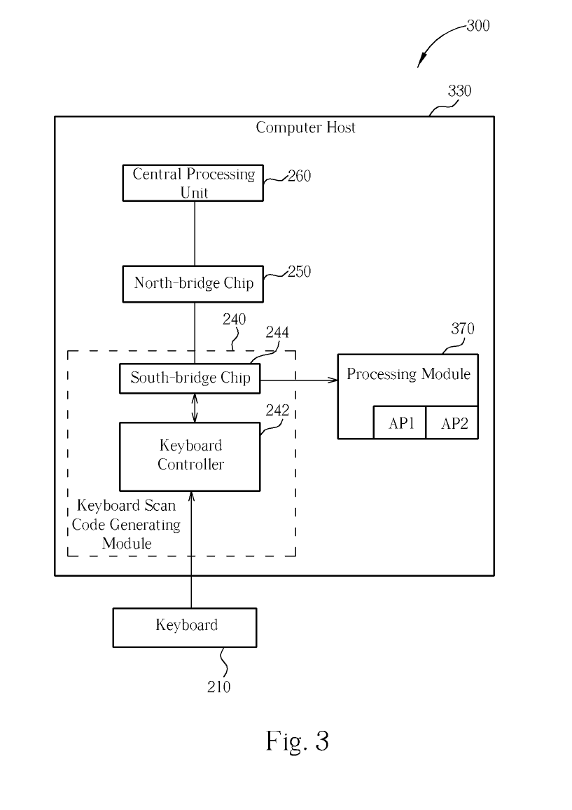

Please refer to FIG. 3. FIG. 3 is a diagram of a computer apparatus 300 for differentiating keys according to another embodiment of the present invention. The computer apparatus 300 shown in FIG. 3 is similar to the computer apparatus 200 shown in FIG. 2, and the difference between them is that a processing module 370 of the computer apparatus 300 including the first layer application program AP1 and the second layer application program AP2 to replace the first processing module 270 and the second processing module 280. When receiving the scan code corresponding to the key generated from the keyboard scan code generating module 240, the processing module 370 checks whether the second layer application program AP2 is executed. When detecting that the second layer application program AP2 is not executed, the processing module 370 executes the event corresponding to the scan code defined in the first layer application program AP1.

Please note that the abovementioned processing module 370 can be implemented by executing the first layer application program AP1 and the second layer application program AP2 through the central processing unit 260, but are not limited to this, and can be implemented in other ways. For example, the processing module 370 can be implemented through hardware, software, or their combination. Furthermore, the first layer application program AP1 and the second layer application program AP2 are installed in an operating system (OS).

Please note that the abovementioned computer apparatuses 200 and 300 are not limited to desktop personal computers (PC), and can be notebook PCs. Hence, the computer host 230 or 330 includes other computer components except the keyboard 210. Those skilled in the art should know that this is not a limitation of the present invention.

Please refer to FIG. 4 together with FIG. 2 and FIG. 1. FIG. 4 is a brief diagram of an example of the keyboard 210 in FIG. 2. The keyboard 210 has a plurality of keys 212, whereof the plurality of keys 212 includes a plurality of hotkeys F₁-Fₙ. Each one of the hotkeys F₁-Fₙ respectively corresponds to a different designated scan code SC_{D1}-SC_{Dn}. The key A is not one of the set hotkeys, wherein the key A corresponds to a scan code SC. In the following description, how each element operates is described by collocating the steps shown in FIG. 1 and the elements shown in FIG. 2.

In Step 102, the first layer application program AP1 and the second layer application program AP2 are set. First, a key of the keyboard 210 is pressed, and then the keyboard scan code generating module 240 generates a scan code corresponding to the key (Steps 104-106). When the first processing module 270 receives the scan code corresponding to the key, the first processing module 270 detects whether the second layer application program AP2 is executed (Step 108). In the following, descriptions are divided into several conditions. In a first condition, if the first processing module 270 detects that the second layer application program AP2 is not executed, it will use the first layer application program AP1 to perform the event corresponding to the scan code defined in the first layer application program AP1 (Step 110). For example, the event corresponding to the scan code is defined as “opening the mailbox” in the first layer application program AP1. In the second condition, if the first processing module 270 detects that the second layer application program AP2 is executed, it will use the first layer application program AP1 to transmit the scan code to the second layer application program AP2 (Step 112) and then the second processing module 280 will use the second layer application program AP2 to perform the event corresponding to the scan code defined in the second layer application program AP2. For example, the event corresponding to the scan code is defined as “playing music” in the second layer application program AP2. In this embodiment, the generated scan code corresponding to the key is fixed, but the events corresponding to scan code defined in the first layer application program AP1 and in the second layer application program AP2 are different. When the second layer application program AP2 is not executed, the event (i.e. “opening the mailbox”) corresponding to the scan code defined in the first layer application program AP1 is performed. When the second layer application program AP2 is executed, the second layer application program AP2 is used for performing the event (i.e. “playing music”) corresponding to the scan code defined in the second layer application program AP2.

Of course, the abovementioned first layer application program AP1 of the first processing module 270 and the second layer application program AP2 of the second processing module 280 are merely exemplary embodiments of the present invention. In other embodiments, more functions are designated into the first layer application program AP1 to provide the computer apparatus 200 with more choices. For example, a comparison function can be added into the first layer application program AP1. Before receiving a scan code corresponding to a key, the scan code corresponding to the pressed key is compared with the designated scan codes SC_{D1}-SC_{Dn} corresponding to the hotkeys F₁-Fₙ. Only when the scan code corresponding to the pressed code is one of the designated scan codes SC_{D1}-SC_{Dn} does the first layer application program AP1 of the first processing module 270 perform the above-mentioned judging step. Therefore, the processing efficiency for differentiating hotkeys can be improved, which can further lower power consumption.

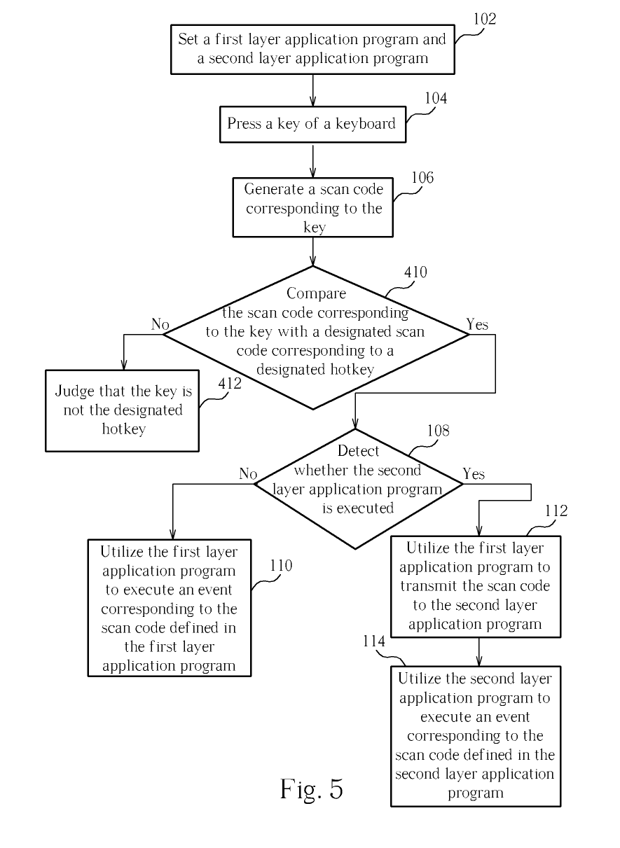

Please refer to FIG. 5. FIG. 5 is a flowchart illustrating a method for differentiating keys according to another exemplary embodiment of the present invention. Please note that the following steps are not limited to be performed according to the sequence shown in FIG. 5 if a roughly identical result can be obtained. The method includes the following steps:

Step 102: Set a first layer application program and a second layer application program.

Step 104: Press a key of a keyboard.

Step 106: Generate a scan code corresponding to the key.

Step 410: Compare the scan code corresponding to the key with a designated scan code corresponding to a designated hotkey. If the scan code corresponding to the key is the designated scan code corresponding to the designated hotkey, go to Step 108; otherwise, go to Step 412.

Step 412: Judge that the key is not the designated hotkey.

Step 108: Detect whether the second layer application program is executed. If the second layer application program is executed, go to Step 112; otherwise, go to Step 110.

Step 110: Utilize the first layer application program to execute an event corresponding to the scan code defined in the first layer application program.

Step 112: Utilize the first layer application program to transmit the scan code to the second layer application program.

Step 114: Utilize the second layer application program to execute an event corresponding to the scan code defined in the second layer application program.

The steps shown in FIG. 5 are similar to that in FIG. 1, and FIG. 5 is a varied embodiment of FIG. 1. The difference between them is that FIG. 5 further adds a comparison function into the first layer application program AP1 (i.e. Steps 410-412). In the following, how each element operates is described by collating the steps shown in FIG. 5 and the elements shown in FIG. 2.

In Step 102, the first layer application program AP1 and the second layer application program AP2 are set. First, a key of the keyboard 210 is pressed, and then the keyboard scan code generating module 240 generates a scan code corresponding to the key (Steps 104-106). When the first processing module 270 receives the scan code corresponding to the key, the first processing module 270 will compare the scan code corresponding to the key with a designated scan code (i.e. one of the designated scan codes SC_{D1}-SC_{Dn}) corresponding to a designated hotkey (i.e. one of the hotkeys F₁-Fₙ) in Step 410. In the following, descriptions are divided into several conditions. In a first condition, assume that the pressed key is the key A, which has a corresponding scan code SC₁. When the first processing module 270 receives the scan code SC₁ corresponding to the key A generated from the keyboard scan code generating module 240, it will compare the scan code SC₁ corresponding to the key A with the designated scan codes SC_{D1}-SC_{Dn} (Step 410). Because the scan code SC₁ corresponding to the key A is not one of the designated scan codes SC_{D1}-SC_{Dn}, Step 412 is performed to determine that the key A is not a designated hotkey of the plurality of hotkeys F₁-Fₙ. In a second condition, assume that the pressed key is the designated hotkey F₁ and the second layer application program AP2 is not executed at this time. When the first processing module 270 receives the scan code SC_{D1} corresponding to the designated hotkey F₁ generated from the keyboard scan code generating module 240, it will compare the scan code SC_{D1} corresponding to the designated hotkey F₁ with the designated scan codes SC_{D1}-SC_{Dn} (Step 410). Because there is a match, Step 108 is performed to detect whether the second layer application program AP2 is executed. The first processing module 270 detects that the second layer application program AP2 is not executed, and the first layer application program AP1 is used for performing the event corresponding to the scan code defined in the first layer application program AP1 (Step 110). For example, the event corresponding to the scan code is defined as “opening the mailbox” in the first layer application program AP1. In a third condition, assume that the pressed key is the designated hotkey F₁ and the second layer application program AP2 is executed at this time. When the first processing module 270 receives the scan code SC_{D1} corresponding to the designated hotkey F₁ generated from the keyboard scan code generating module 240, it will compare the designated scan code SC_{D1} corresponding to the pressed designated hotkey F₁ with the designated scan codes SC_{D1}-SC_{Dn} (Step 410). Because there is a match, Step 108 is performed to detect whether the second layer application program AP2 is executed. The first processing module 270 detects that the second layer application program AP2 is executed, and the first layer application program AP1 is used for transmitting the scan code to the second layer application program AP2 (Step 112) and then the second processing module 280 utilizes the second layer application program AP2 to perform the event corresponding to the scan code defined in the second layer application program AP2. For example, the event corresponding to the scan code is defined as “playing music” in the second layer application program AP2.

These embodiments above are presented merely for describing applications of the present invention, and in no way should be considered to be limitations of the scope of the present invention. It will be obvious to those skilled in the art that various modifications of the first layer application program AP1 in the first processing module 270 and the second layer application program AP2 in the second processing module 280 may be made without departing from the spirit of the present invention.

The abovementioned embodiments are presented merely for describing the present invention, and in no way should be considered to be limitations of the scope of the present invention. The abovementioned computer apparatuses 200 and 300 can be a desktop PC or a notebook PC, but are not limited to this only and can be computer apparatuses of other types. The first processing module 270 can be implemented by executing the first layer application program AP1 through the central processing unit 260 and the second processing module 280 can be implemented by executing the second layer application program AP2 through the central processing unit 260, or the processing module 370 can be implemented by executing the first layer application program AP1 and the second layer application program AP2 through the central processing unit 260, but are not limited to them and can be implemented in other ways. In addition, the first processing module 270 and the second processing module 280 above are presented merely for describing applications of the present invention. Those skilled in the art should appreciate that various modifications of the first layer application program AP1 in the processing module 270 and the second layer application program AP2 may be made without departing from the spirit of the present invention. The number n of the abovementioned hotkeys F₁-Fₙ is not a fixed value and can be adjusted according to user demands. Please note that, the steps of the abovementioned flows are not limited to be performed according to the sequence shown in the embodiments above. Various modifications can be made without departing from the spirit of the present invention by those skilled in the art.

In summary, the present invention provides a method and related computer apparatus for differentiating keys. Through setting the first layer application program AP1 and the second layer application program AP2, the events corresponding to the designated scan code defined in the first layer application program AP1 and in the second layer application program AP2 are different although the designated scan code generated from the same designated hotkey (F₁-Fₙ) is identical. Therefore, when the second layer application program AP2 is not executed, the first layer application program AP1 is used for performing the event (i.e. “opening the mailbox”) corresponding to the scan code defined in the first layer application program AP1. On the other hand, when the second layer application program AP2 is executed, the second layer application program AP2 is used for performing the event (i.e. “playing music”) corresponding to the scan code defined in the second layer application program AP2. In other words, assuming that the keyboard hotkeys (such as F₁-Fₙ) produced by keyboard manufactures have passed through Microsoft's certification, the first layer application program AP1 is used for performing the hotkey functions passed through Microsoft's certification. However, the layered key-differentiating mechanism further provides a second layer application program AP2 to replace the first layer application program AP1 to provide other hotkey functions against the scan codes corresponding to the same keyboard hotkeys. Furthermore, a comparison function can be added into the first layer application program AP1 of the first processing module 270 to improve the efficiency for differentiating hotkeys further. Therefore, not only can users set different hotkey functions according to their demands, but manufacturers also can save time and costs of passing through certifications, which is a great boon in consideration of convenience and economy.

Those skilled in the art will readily observe that numerous modifications and alterations of the device and method may be made while retaining the teachings of the invention.

What is claimed is:

1. A method for differentiating keys comprising:
setting a first layer application program and a second layer application program;
detecting whether the second layer application program is executed to generate a detection result when receiving a scan code corresponds to a key; and
selectively utilizing the first layer application program or the second layer application program to determine an event corresponding to the scan code.

2. The method of claim 1, wherein the step of generating the detection result comprises:
executing the first layer application program to receive the scan code and detecting whether the second layer application program is executed; and
the step of determining the event corresponding to the scan code comprises:
when the detection result indicates that the second layer application program is executed, utilizing the first layer application program to transmit the scan code to the second layer application program, and utilizing the second layer application program to execute the event corresponding to the scan code defined in the second layer application program.

3. The method of claim 1, wherein the step of generating the detection result comprises:
executing the first layer application program to receive the scan code and detecting whether the second layer application program is executed; and
the step of determining the event corresponding to the scan code comprises:
when the detection result indicates that the second layer application program is not executed, utilizing the first layer application program to execute the event corresponding to the scan code defined in the first layer application program.

4. The method of claim 1, wherein the event corresponding to the scan code defined in the second layer application program is different from the event corresponding to the scan code defined in the first layer application program.

5. The method of claim 1, wherein the key is a designated hotkey.

6. The method of claim 1 further comprising:
comparing the scan code corresponding to the key with a designated scan code corresponding to a designated hotkey;
wherein the step of detecting whether the second layer application program is executed is only performed when the scan code is the designated scan code.

7. A computer apparatus comprising:
a keyboard having at least one key; and
a computer host, coupled to the keyboard, comprising a first layer application program and a second layer application program, wherein when receiving a scan code corresponding to the key, the computer host detects whether the second layer application program is executed to generate a detection result, and selectively utilizes the first layer application program or the second layer application program to determine an event corresponding to the scan code according to the detection result.

8. The computer apparatus of claim 7, wherein the computer host comprises:
a keyboard scan code generating module, coupled to the keyboard, for generating the scan code corresponding to the key when the key is pressed;
a first processing module, coupled to the keyboard scan code generating module, for detecting whether the second layer application program is executed when receiving the scan code corresponding to the key received from the keyboard scan code generating module; and
a second processing module, coupled to the first processing module, wherein when the first processing module detects that the second layer application program is executed, the first processing module transmits the scan code to the second processing module and the second processing module executes the event corresponding to the scan code defined in the second layer application program.

9. The computer apparatus of claim 8, wherein the first processing module is implemented by executing the first layer application program through a central processing unit, and the second processing module is implemented by executing the second layer application program through the central processing unit.

10. The computer apparatus of claim 7, wherein the computer host comprises:
a keyboard scan code generating module, coupled to the keyboard, for generating the scan code corresponding to the key when the key is pressed; and
a processing module, coupled to the keyboard scan code generating module, for detecting whether the second layer application program is executed when receiving the scan code corresponding to the key received from the keyboard scan code generating module, and for executing the event corresponding to the scan code defined in the first layer application program when detecting that the second layer application program is not executed.

11. The computer apparatus of claim 10, wherein the processing module is implemented by executing the first layer application program and the second layer application program through a central processing unit.

12. The computer apparatus of claim 7, wherein the first layer application program and the second layer application program are installed in an operating system (OS).

13. The computer apparatus of claim 7, wherein the key is a designated hotkey.

14. The computer apparatus of claim 7, wherein the computer host comprises:
a keyboard scan code generating module, coupled to the keyboard, for generating the scan code corresponding to the key when the key is pressed; and
a processing module, coupled to the keyboard scan code generating module, for comparing the scan code corresponding to the key with a designated scan code corresponding to a designated hotkey, wherein only when the scan code corresponding to the pressed key is the designated scan code, the processing module detects whether the second layer application program is executed to generate the detection result and selectively executes the event corresponding to the scan code defined in the first layer application program or defined in the second layer application program according to the detection result.

15. The computer apparatus of claim 14, wherein the processing module is implemented by executing the first layer application program and the second layer application program through a central processing unit.

16. A computer apparatus comprising:
a keyboard having at least one key;
a keyboard controller, for generating a scan code corresponding to the key when the key is pressed;
a first processing module, for detecting whether the second layer application program is executed when receiving the scan code corresponding to the key, wherein the first processing module executes an event corresponding to the scan code defined in the first layer application program when the second layer application program is not executed; and
a second processing module, wherein when the first processing module detects that the second layer application program is executed, the first processing module transmits the scan code to the second processing module and the second processing module executes an event corresponding to the scan code defined in the second layer application program.

17. The computer apparatus of claim 16, wherein the first processing module is implemented by executing the first layer application program through a central processing unit, and the second processing module is implemented by executing the second layer application program through the central processing unit.
